(19) United States
(12) Patent Application Publication
(10) Pub. No.: US 2023/0309273 A1
(43) Pub. Date: Sep. 28, 2023

(54) SYSTEM, METHOD, AND NON-TRANSITORY COMPUTER READABLE STORAGE MEDIUM

(71) Applicant: NEC Corporation, Minato-ku, Tokyo (JP)

(72) Inventors: Nirmal Singh RAJPUT, Tokyo (JP); Masaki Chiba, Tokyo (JP); Yoshinori Miyamoto, Tokyo (JP); Junichi Miyamoto, Tokyo (JP); Minoru Yoshikawa, Tokyo (JP)

(73) Assignee: NEC Corporation, Minato-ku, Tokyo (JP)

(21) Appl. No.: 18/020,125

(22) PCT Filed: Aug. 13, 2020
(86) PCT No.: PCT/JP2020/030802

§ 371 Date: Feb. 7, 2023

(51) Int. Cl. H05K 7/20; G06F 1/20

(52) U.S. Cl. CPC H05K 7/20836; G06F 1/206; H05K 7/20136; H05K 7/20745

(57) ABSTRACT

The present disclosure can provide a system, method and non-transitory computer readable storage medium capable of generating a uniform airflow at a heat exchanger surface. A system includes: a cooling unit body (11, 21) having an airflow inlet (18, 28) and an airflow outlet (15, 25); a heat exchanger (12, 22) provided inside the cooling unit body; and a plurality of fans (16, 17, 26, 27) provided at the airflow inlet. The system may include air velocity sensors (265, 275) provided at the heat exchanger (22).

### TECHNICAL FIELD

The present disclosure relates to a system, a method and a non-transitory computer readable storage medium for maintaining and improving airflow distribution uniformity at a heat exchanger surface in a compact size cooling system.

### BACKGROUND ART

A local cooling system such as a modular cooling unit is placed near a rack air outlet. The local cooling system can operate at higher temperatures and a lower airflow, resulting in higher thermal efficiency. Usually, a space between a rack top surface and a ceiling is limited, and thus a theoretical height of the modular cooling unit is restricted to less than 1 m. In reality, some space is required for a coolant pipe and auxiliary equipment, such as a rack cable tray, and thus the height of the modular cooling unit is restricted to 0.5 m to 0.7 m.

In a cooling system, it is desired that a fan required for airflow generation be placed in a pull setting, i.e., pulling airflow from a heat exchanger, in order to generate a uniform airflow. However, in a pull setting, a space between a rack top surface and a ceiling is limited, and thus a fan size is reduced and hence airflow becomes smaller. In order to overcome this problem, since, in a push setting, a surface area larger than that of the above space in a pull setting is available below the heat exchanger, a fan larger than that which can be placed in the pull setting can be placed in the push setting, i.e. pushing airflow at a heat exchanger surface, and generating sufficient airflow.

### CITATION LIST

[Non Patent Literature]

NPL 1: Green aisle by Toyo netsu kogyou kabushiki kaisha (https://www.tonets.co.jp/Portals/0/images/business/request/pdf/ [symbol] .pdf)

### SUMMARY OF INVENTION

### Technical Problem

Placing a larger fan in a push setting can cause a higher airflow to be generated in a modular cooling unit. However, the generated airflow is non uniform at heat exchanger surface, thus resulting in poor thermal efficiency. This problem can be solved by increasing the distance between the fan and the heat exchanger to less than 6-7 times a fan depth, where the fan depth is less than 50 mm. However, for a compact modular cooling unit of less than 200 mm in height, maintaining a distance between the fan and the heat exchanger surface to less than less than 6-7 times a fan depth is not an option.

The present disclosure has been accomplished to solve the above problems and an object of the present disclosure is thus to provide a system, method and non-transitory computer readable storage medium capable of generating a uniform airflow at a heat exchanger surface.

### Solution to Problem

A system according to a first exemplary aspect of the present disclosure includes
a cooling unit body having an airflow inlet and an airflow outlet;
a heat exchanger provided inside the cooling unit body; and
a plurality of fans provided at the airflow inlet.

A method of tuning a fan operation according to a second exemplary aspect of the present disclosure includes: in a system including a cooling unit body having an airflow inlet and an airflow outlet; a heat exchanger provided inside the cooling unit body; and a plurality of fans provided at the airflow inlet, wherein the plurality of fans are configured to be connected to respective power lines and to be connected to respective signal lines, the method includes:
setting a fan operation point to the plurality of fans;
fetching actual fan operation points for the plurality of fans;
calculating an absolute difference value between the set operation points and the actual operation points;
comparing the absolute difference value with a threshold value; and
if any fan has an absolute difference value greater than the threshold value, setting a redundant fan operation set point to the plurality of fans.

A non-transitory computer readable storage medium according to a third exemplary aspect of the present disclosure is a non-transitory computer readable storage medium storing instructions to cause a computer to perform the steps of:
setting a fan operation point;
fetching a current fan operation point;
calculating a difference between the set fan operation point and the current fan operation point; and
comparing the difference between the set fan operation point and the current fan operation point with a threshold value.

### Advantageous Effects of Invention

According to the exemplary aspects of the present disclosure, it is possible to provide a system, method and non-transitory computer readable storage medium capable of generating a uniform airflow at a heat exchanger surface.

### BRIEF DESCRIPTION OF DRAWINGS

FIG. 1 is a diagram showing a placement example of components in a data center.

FIG. 2 shows a system with the plurality of fans in a push setting according to some embodiments.

FIG. 3 is a flowchart illustrating a method of tuning a fan operation point according to some embodiments.

FIG. 4 is a diagram illustrating a fan operation point tuning in a system with a plurality of fans according to some embodiments.

FIG. 5 shows an example system in which a plurality of fans are shifted toward a heat exchanger header according to some embodiments.

FIG. 6 shows an example system in which each fan has respective power lines and respective signal lines according to some embodiments.

FIG. 7 is a flowchart illustrating a method of determining a fan redundant operation.

FIG. 8 shows an example system which has a detachable fan casing according to other embodiments.

FIG. 9 shows an example system which has a detachable air interruption casing and plate according to other embodiments.

FIG. 10 shows an example system which has a detachable air filer according to other embodiments.

FIG. 11 is a block diagram illustrating a configuration example of the controller.

### DESCRIPTION OF EMBODIMENTS

Hereinafter, specific embodiments to which the above-described example aspects of the present disclosure are applied will be described in detail with reference to the drawings. In the drawings, the same elements are denoted by the same reference signs, and repeated descriptions are omitted for clarity of the description.

Example embodiments are described herein with reference to block diagrams and/or flowchart illustrations of computer-implemented methods, apparatus (systems and/or devices) and/or computer program products. It is understood that a block of the block diagrams and/or flowchart illustrations, and combinations of blocks in the block diagrams and/or flowchart illustrations, can be implemented by computer program instructions that are performed by one or more computer circuits. These computer program instructions may be provided to a processor circuit of a general purpose computer circuit, special purpose computer circuit, and/or other programmable data processing circuit to produce a machine, such that the instructions, which execute via the processor of the computer and/or other programmable data processing apparatus, transform and control transistors, values stored in memory locations, and other hardware components within such circuitry to implement the functions/acts specified in the block diagrams and/or flowchart block or blocks, and thereby create means (functionality) and/or structures for implementing the functions/acts specified in the block diagrams and/or flowchart block(s).

For achieving a higher airflow in compact and modular cooling units, a fan is placed in a push setting instead of a pull setting due to availability of an area, as utilized in NPL 1, larger than that available in a pull setting. However, the placement of such a fan will result in non-homogeneous airflow distribution at a heat exchanger surface and thus thermal efficiency is reduced.

In order to control airflow distribution at a heat exchanger surface in a compact and modular cooling unit, and in order to achieve higher thermal efficiency by generating homogeneous airflow, a plurality of fans are utilized in a push setting. Each fan operation point can be tuned to achieve more homogenous airflow distribution.

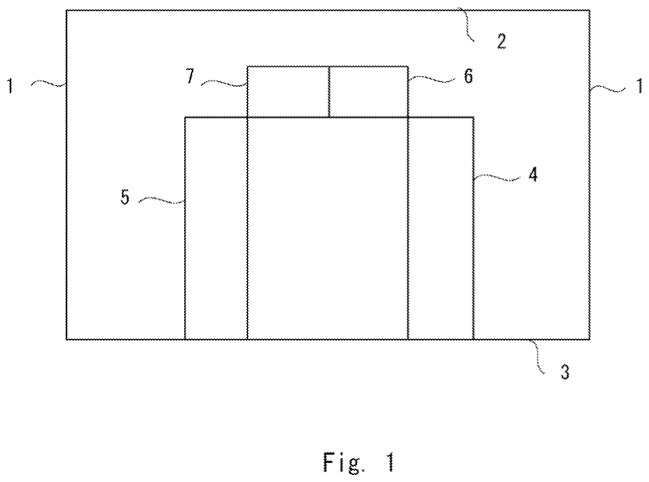

FIG. 1 is a diagram showing a placement example of components in a data center.

As shown in FIG. 1, a data center comprises side walls 1, a ceiling 2 and a floor 3. A plurality of racks 4, 5 are placed on the floor 3 in the data center. A plurality of modular cooling units 6, 7 are installed between the ceiling 2 and the top surfaces of the rack 4, 5.

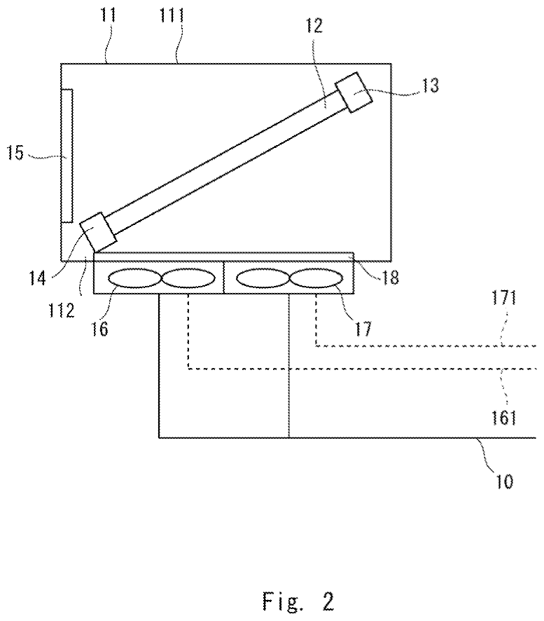

As shown in FIG. 2, a system comprises a cooling unit body 11 which has a heat exchanger 12 with a liquid header 14 and a gas header 13, an airflow outlet 15, an airflow inlet 18 and two fans 16 and 17. Each of the fans 16 and 17 has two oval-shaped blades in a fan exterior body. The bottom surface 112 of the cooling unit body 11 may partially contact the top surface of rack 4, 5. The airflow outlet 15 is provided in a sidewall of the cooling unit body 11. The airflow inlet 18 is provided in the bottom surface 112 of the cooling unit body 11. The fan power is supplied by a common power line 10. The heat exchanger 12 is arranged obliquely inside the cooling unit body 11 because the height of the cooling unit body 11 is smaller than the longitudinal length of the heat exchanger 12. In FIG. 2, two fans 16 and 17 are shown, but the present disclosure is not limited to two fans and can be applied to a larger number of fans (e.g. three or more fans). The fan receives air and supplies air to the airflow inlet 18, from where air flows across the heat exchanger 12 surface and finally escapes from the outlet 15.

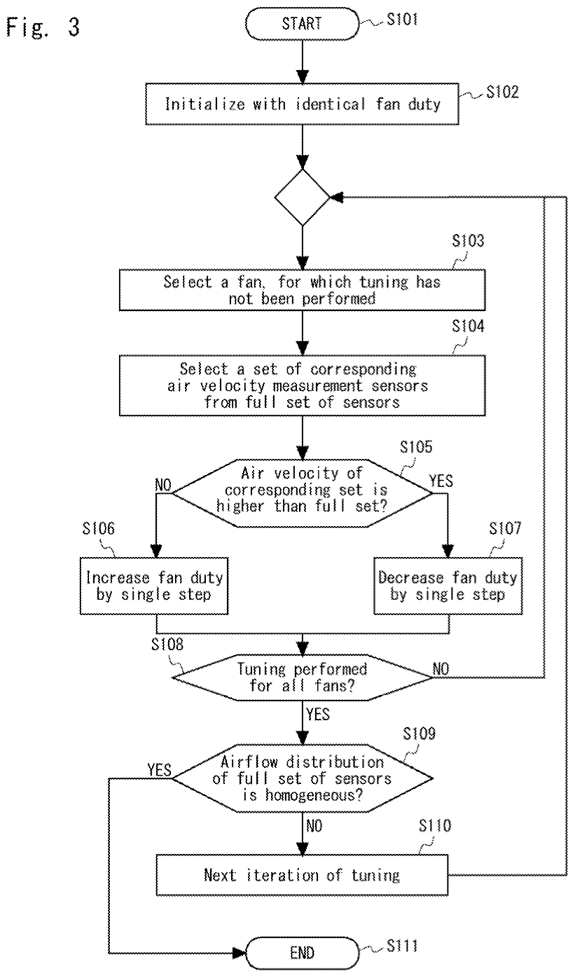

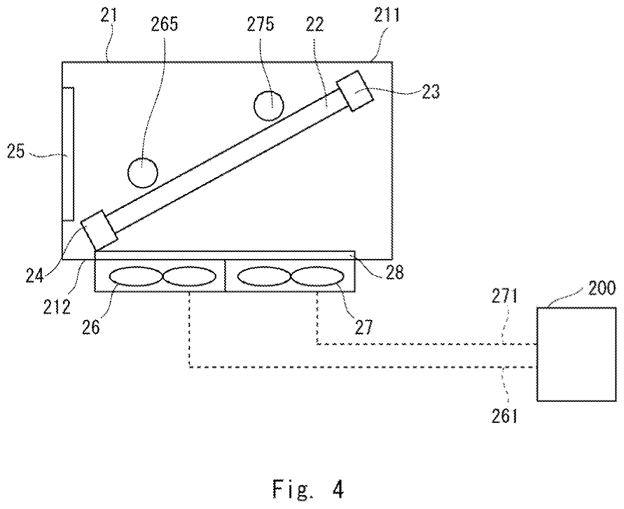

Since the plurality of fans 16 and 17 push airflow at the heat exchanger 12, the airflow distribution will be more homogeneous as compared to that in the case of a single large fan. At the same time, each individual fan 16, 17 can be controlled independently by independent signal line 161, 171 respectively. The fan duty tuning can be performed according to a flowchart of FIG. 3 and FIG. 4. Fan operation parameters can be defined, but not limited to, in terms of fan RPM, fan duty, tuning, etc.

With reference to FIGS. 3 and 4, the fan duty tuning will be described below.

In FIG. 4, most components are similar to those of FIG. 2. In FIG. 4, air velocity sensors 265, 275 are provided nearby the heat exchanger 22. The air velocity sensor 265 corresponds to a fan 26 and can measure the air velocity of airflow from the fan 26. Similarly, the air velocity sensor 275 corresponds to a fan 27 and can measure the air velocity of airflow from the fan 27. The controller 200 can control the fans 26, 27 via signal lines 261, 271 based on the values of the air velocity sensors 265, 275. Accordingly, the system utilizes a plurality of fans which can be controlled individually to maintain uniform airflow at heat exchanger surface in compact cooling system.

In Step S101, the controller 200 starts the individual fan duty tuning process. In Step S102, the control unit 200 initializes all fans with the identical fan duty. In FIG. 4, as an example, the Fans 26 and 27 can be initiated with 60% fan duty.

In Step S103, the controller 200 selects a fan for which tuning has not been performed. The fan duty tuning is performed for the selected fan. In FIG. 4, as an example, a fan 26 is selected. The fan duty tuning is performed for the fan 26.

A set of air velocity sensors are placed at the heat exchanger 22 air inlet or outlet surface. In Step S104, the controller 200 selects a set of air velocity sensors corresponding to the fan selected in Step S103 out of the full set of air velocity sensors. As an example, an air velocity sensor 265 placed against the air outlet heat exchanger 22 surface is selected out of the full set of sensors (i.e. 265 and 275).

In Step S105, the controller 200 compares an air velocity of the selected air velocity sensor with that of the full set of air velocity sensors. As an example, the value of the sensor 265 is compared with the average of the full set of sensors (i.e. 265 and 275). In the case of three or more sensors, an average of values may be used. At the same time, a variety of parameters such as standard deviation can be utilized.

In Step S106, if the air velocity sensor 265 value is smaller than that of the air velocity sensor 275, then the controller 200 increases a fan duty of the fan 26 by a single step. As an example, the fan duty step is 5%, therefore, the fan 26 duty is increased from 60% to 65%. Accordingly, the airflow from both of the fans 26, 27 can be uniform.

On the other hand, in Step S107, if the value of the air velocity sensor 265 is greater than that of the sensor 275, then the controller 200 decreases a fan duty of the fan 26 by a single step. As an example, the fan duty step is 5%, therefore, the fan 26 duty is decreased from 60% to 55%. Accordingly, the airflow from both the fans 26, 27 can be uniform.

In Step S108, the controller 200 checks whether the fan duty tuning has been performed for all the fans. If not, then the controller 200 again starts the process from S103 by selecting a fan from the remaining fans. As an example, the fan 27 is selected.

In Step S109, after S108, if tuning is performed for all the set of fans, then the controller 200 calculates an airflow distribution. As an example, standard deviation can be utilized as airflow distribution parameters to decide whether airflow is homogenous or not.

In Step S110, if the controller 200 concludes that the airflow distribution isn't homogenous (NO in S109), then a next iteration of the fan duty tuning is performed. In Step S111, if the controller 200 concludes that the airflow distribution is homogenous (YES in S109), the controller 200 finishes the process with the tuning individual fan duty for the homogenous airflow at the heat exchanger surface exchanger surface 22.

In various embodiments, the exemplary steps of FIG. 3 may be performed in various orders, performed in parallel, or omitted. Additional processing steps may also be implemented.

This embodiment can implement a system, method and non-transitory computer readable storage medium capable of generating a uniform airflow at a heat exchanger surface.

### Other Embodiments

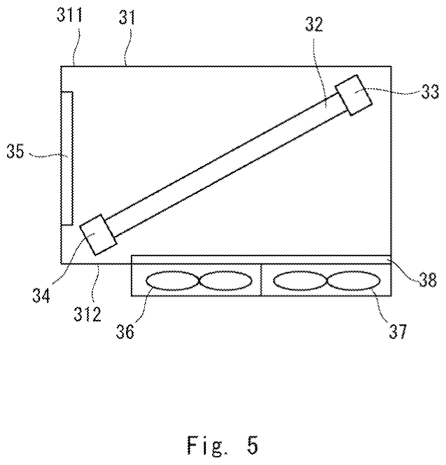

In other embodiment as shown in FIG. 5, fans 36 and 37 are shifted from the center of the bottom surface 312 of the cooling unit body 31 towards a gas header 33 of a heat exchanger 32. In FIG. 5, most components are similar to those of FIG. 2. The gas header 33 of the heat exchanger 32 is located at a higher position than that of the liquid header 34. The liquid header 34 is located close to the fans 36 and 37, while the gas header 33 is located distally from the fans 36 and 37. The dead space between the fan 36 and a liquid header 34 can often result in a higher pressure drop. In FIG. 5, the area between the liquid header 34 and the body surface 312 is called as “dead space” because airflow across this region is negligible as compared to the core of the heat exchanger 32. As used herein, “dead space” is a space which has relatively much higher airflow pressure drop when compared to the rest of the system, i.e. resulting in smaller airflow compared to rest of the system. By shifting the fans 36 and 37 towards the gas header 33, the dead space between the fan 36 and the liquid header 34 can be avoided. In this embodiment, the liquid header 34 is at a lower height than that of the gas header 33 as a refrigerant (e.g., fluorocarbon refrigerants) inside the heat exchanger 32 is evaporative in nature. However, depending upon application such as single phase cooling, such header positions are irrelevant and fans can be shifted from the center of the bottom surface 312 of the cooling unit body 31 towards one of the headers such that the distance between the fan and the heat exchanger increases. By avoiding the dead space, airflow distribution uniformity at a heat exchanger surface can be improved.

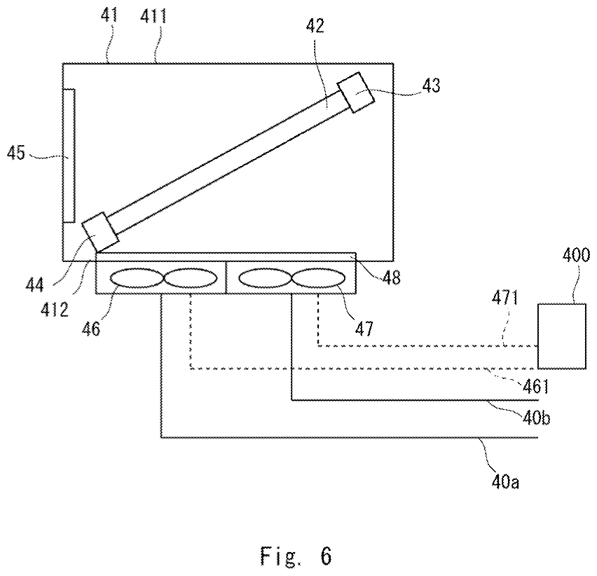

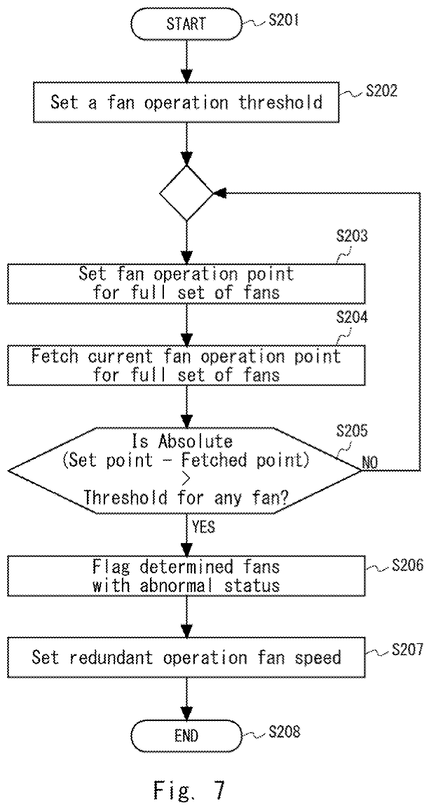

In other embodiment as shown in FIG. 6, individual fans 46, 47 are provided with separate power lines 40a, 40b and separate signal lines 461, 471. In FIG. 6, the fan 46 is provided with the power line 40a and the signal line 461, while the fan 47 is provided with the power line 40b and the signal line 471. In FIG. 6, most components are similar to those of FIG. 2. The signal is sent and received by the controller 400, which can send an operation point command and receive the current operation point. By utilizing a plurality of fans with separate power lines, redundant fan operation can be performed. In case of a fan failure, the remaining fan(s) can be utilized to continue operation. Accordingly, the need for expensive emergency maintenance can be avoided. As an example, in case of a failure of the fan 46, the fan 47 can be utilized to continue the cooling operation until maintenance. The process of fan operation by the controller 400 is shown in FIG. 7 and explained below.

With reference to FIG. 7, a fan operation set point process will be described below.

In S201, the controller 400 starts the fan operation set point process. As an example, fan duty will be utilized. Other parameters such as a fan RPM can also be utilized. In S202, the controller 400 sets, via a user input, a fan operation threshold for distinguishing a normal operation from an abnormal operation. If the difference between the set operation point and an actual operation is greater than a threshold, the fan will be flagged with the abnormal status, and then the flagged fan can be replaced during maintenance. As an example, a threshold is set at 10% for fan duty.

In S203, the controller 400 sets an operation point for the full set of fans. As an example, the controller 400 sets 60% fan duty to the fans 46 and 47. In S204, the controller 400 fetches a current operation point of each fan. As an example of a normal operation, the fan 46 is operating at 58% and the fan 47 is operating at 55%. As an example of an abnormal operation, the fan 46 is damaged and non-operation, therefore operating at 0%, while the fan 47 is operating at 55%.

In S205, the controller 400 calculates the difference between the set operation point and the current (or actual) operation point of a fan. As an example of normal operation, the operation difference when the fan 46 is operating at 58% is an absolute value of (60−58)=2%, while the operation difference when the fan 47 is operating at 55% is an absolute value of (60−55)=5%. Here, both of the fans 46 and 47 have an operation difference below the threshold (in this case, 10%) set by the user input in S202. As an example of an abnormal operation, the operation difference when the fan 46 is operating at 0% is the absolute value of (60−0)=60%, while the operation difference when the fan 47 is operating at 55% is the absolute value of (60−55)=5%. Here, the fan 46 has an operation difference above the threshold (in this case, 10%) set in S202, but the fan 47 has an operation difference below the threshold (in this case, 10%) set in S202.

In S206, the fan with the operation difference greater than threshold is flagged to be replaced during maintenance. As an example of an abnormal operation, the operation difference for fan 46 was 60%, which is higher than the threshold (10%) set in S202, therefore the fan is flagged.

In S207, if an abnormal operation is detected in S206, then the remaining fans are operated at a redundant operation set point. As an example, the redundant operation set point is 80%. In S208, the controller 400 finishes the process.

The system according to this embodiment can distinguish the normal operation from the abnormal operation for a plurality of fans and flag the fan which operates abnormally.

In various embodiments, the exemplary steps of FIG. 7 may be performed in various orders, performed in parallel, or omitted. Additional processing steps may also be implemented.

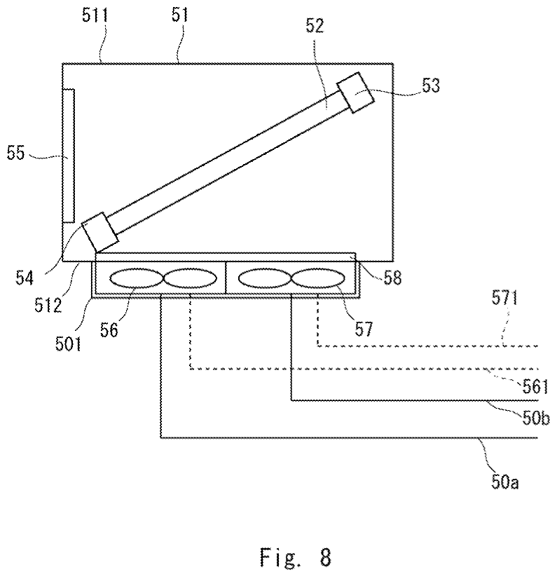

In yet other embodiments as shown in FIG. 8, a plurality of fans are placed inside a fan casing such that during maintenance, the fan casing can be removed without having to uninstall the modular cooling unit body 51 from the ceiling. In FIG. 8, most components are similar to those of FIG. 1. In FIG. 8, fans 56 and 57 are installed inside a fan casing 501 which is detachable from a modular cooling unit body 51. The present invention utilizes a plurality of fans which are small in size and light weight so that such detachability is made feasible along with the feasibility of a redundant operation.

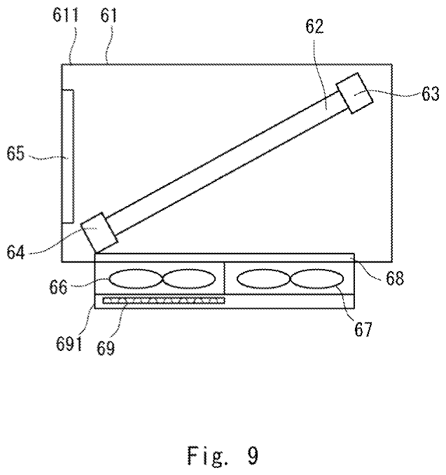

In other embodiment as shown in FIG. 9, an airflow interruption casing 691 with an airflow interruption plate 69 is placed below the fan 66. In FIG. 9, most components are similar to those of FIG. 2. In the case of the redundant operation, as an example, in case of a failure of the fan 66, due to a pressure difference between the inside and the outside of the fan 67, high pressure air inside the modular cooling unit body 61 can recirculate and will result in reduced fan efficiency. An airflow interruption plate 69 can be inserted inside the airflow interruption casing 691 which will prevent such airflow recirculation. Since, the airflow interruption plate 69 can be inserted by any non-specialized person, the requirement of expensive emergency maintenance can be avoided while ensuring maximum fan efficiency.

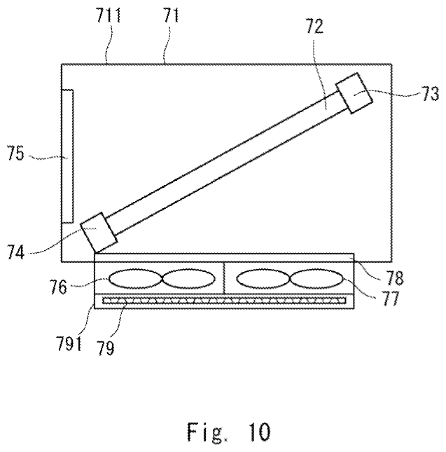

In other embodiment as shown in FIG. 10, an air filter 79 is placed inside an air filter casing 791. The air filter casing 791 encloses air filter 79 which in turn ensures that dirt and other particles doesn't enter inside the cooling unit 71 and fans 76, 77 and facilitates in maintenance process of air filter replacement. In FIG. 10, most components are similar to those of FIG. 2. In the case of maintenance, the air filter casing 791 can be detached from the modular cooling unit body 71 and the air filter 79 can be replaced without having to uninstall fan casing 501 (in FIG. 8) or a modular cooling unit body 51 (in FIG. 8) from a ceiling.

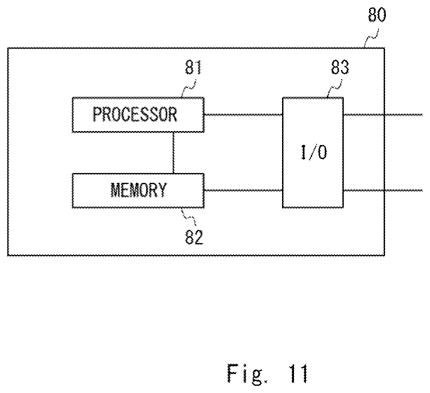

FIG. 11 is a block diagram illustrating a configuration example of the controller 200 or 400 (e.g. information processing apparatus). In one of the embodiments, the controller may comprise a controller body 80, a processor 81 (e.g., CPU) which can calculate and compare numbers, a memory 82 (e.g. RAM) which can store information, and an I/O 83 which can communicate with an external device such as a fan. The I/O 83 may include, for example, a network interface card (NIC) compliant with, for example, IEEE 802.3 series.

The processor 81 performs processing of the information processing apparatus described with reference to the sequence diagrams and the flowchart in the above embodiments by reading software (computer program) from the memory 82 and executing the software. The processor 81 may be, for example, a microprocessor, an MPU or a CPU. The processor 81 may include a plurality of processors.

The processor 81 may include a plurality of processors. For example, the processor 81 may include a modem processor (e.g., DSP) which performs the digital baseband signal processing, a processor (e.g. DSP) which performs the signal processing of the GTP-U?UDP/IP layer in the X2-U interface and the S1-U interface, and a protocol stack processor (e.g., a CPU or an MPU) which performs the control plane processing.

The memory 82 is configured by a combination of a volatile memory and a non-volatile memory. The memory 82 may include a storage disposed apart from the processor 81. In this case, the processor 81 may access the memory 82 via an I/O interface.

The memory 82 is used to store software module groups. The processor 81 can perform processing of the information processing apparatus described in the above embodiments by reading these software module groups from the memory 82 and executing the software module groups.

In the aforementioned embodiments, the program(s) can be stored and provided to a computer using any type of non-transitory computer readable media. Non-transitory computer readable media include any type of tangible storage media. Examples of non-transitory computer readable media include magnetic storage media (such as flexible disks, magnetic tapes, hard disk drives, etc.), optical magnetic storage media (e.g., magneto optical disks), Compact Disc Read Only Memory (CD-ROM), CD-R, CD-R/W, and semiconductor memories (such as mask ROM, Programmable ROM (PROM), Erasable PROM (EPROM), flash ROM, Random Access Memory (RAM), etc.). The program(s) may be provided to a computer using any type of transitory computer readable media. Examples of transitory computer readable media include electric signals, optical signals, and electromagnetic waves. Transitory computer readable media can provide the program to a computer via a wired communication line (e.g., electric wires, and optical fibers) or a wireless communication line.

While the present disclosure has been described above with reference to the embodiments, the present disclosure is not limited to the aforementioned description. Various changes that may be understood by one skilled in the art may be made on the configuration and the details of the present disclosure within the scope of the present disclosure.

Part of or all the foregoing embodiments can be described as in the following appendixes, but the present invention is not limited thereto.

### (Supplementary Note 1)

A system comprising:
a cooling unit body having an airflow inlet and an airflow outlet;
a heat exchanger provided inside the cooling unit body; and
a plurality of fans provided at the airflow inlet.

### (Supplementary Note 2)

A system according to note 1, further comprising a plurality of air velocity sensors provided at the heat exchanger, the plurality of air velocity sensors provided corresponding to the plurality of fans.

### (Supplementary Note 3)

A system according to note 1, wherein the cooling unit body is installed between a rack top surface and a ceiling.

### (Supplementary Note 4)

A system according to note 1, wherein the plurality of fans are configured to be connected to respective power lines and to be connected to respective signal lines.

### (Supplementary Note 5)

A system according to note 1, further comprising a controller connected via separate signal lines to the plurality of fans, the controller configured to control the plurality of fans.

### (Supplementary Note 6)

A system according to note 5, wherein the controller is configured to set a fan operation set point and fetch a current fan operation point.

### (Supplementary Note 7)

A system according to note 6, wherein the controller is further configured to calculate an absolute difference value between the set operation points and an actual operation points;
compare the absolute difference value with a threshold value; and
if any fan has the absolute difference value greater than threshold value,
set a redundant fan operation set point to the plurality of fans.

### (Supplementary Note 8)

A system according to note 1, wherein the plurality of fans are shifted towards one header of the heat exchanger so that the distance between the fan and the heat exchanger increases.

### (Supplementary Note 9)

A system according to note 1, further comprising a casing in which the plurality of fans are placed, wherein the casing is detachable and can be removed without having to uninstalling the cooling unit body from an installed location.

### (Supplementary Note 10)

A system according to note 1, further comprising an air interruption casing provided below the fan and configured to receive an air interruption plate.

### (Supplementary Note 11)

A system according to note 1, further comprising an air filter casing which is removable without having to uninstalling the fan casing.

### (Supplementary Note 12)

A method of tuning a fan operation in a system including: a cooling unit body having an airflow inlet and an airflow outlet; a heat exchanger provided inside the cooling unit body; and a plurality of fans provided at the airflow inlet, wherein the plurality of fans are configured to be connected to respective power lines and to be connected to respective signal lines, the method comprising:
setting a fan operation point to the plurality of fans;
fetching actual fan operation points for the plurality of fans;
calculating an absolute difference value between the set operation points and the actual operation points;
comparing the absolute difference value with a threshold value; and
if any fan has an absolute difference value greater than the threshold value,
setting a redundant fan operation set point to the plurality of fans.

### (Supplementary Note 13)

The method according to note 12, comprising:
if any fan has an absolute difference value greater than the threshold value,
then flagging the fan for maintenance.

### (Supplementary Note 14)

The method according to note 12, wherein the redundant fan operation set point is higher than a normal fan operation set point.

### (Supplementary Note 15)

The method according to note 12, comprising:
selecting a fan to be tuned;
selecting one or more air velocity sensors corresponding to the selected fan the from a plurality of air velocity sensors provided at the heat exchanger;
fetching an air velocity value from one of the selected one or more air velocity sensors;
fetching an air velocity value from one of the full set of air velocity sensors;
comparing the air velocity value from the selected set of air velocity sensor with that of the full set of air velocity sensors;
increasing a fan operation point by single step if the air velocity value from selected set of air velocity sensor is smaller than that of one of the full set of air velocity sensors; and
decreasing a fan operation point by single step if the air velocity value from one of the selected set of air velocity sensors is greater than that of one of the full set of air velocity sensors.

### (Supplementary Note 16)

The method according to note 15, wherein the air velocity of the selected sensor is compared with the remaining set of air velocity sensors.

### (Supplementary Note 17)

A non-transitory computer readable storage medium storing instructions to cause a computer to perform the steps of:
setting a fan operation point;
fetching a current fan operation point;
calculating a difference between the set fan operation point and the current fan operation point; and
comparing the difference between the set fan operation point and the current fan operation point with a threshold value.

### INDUSTRIAL APPLICABILITY

The system and method for maintaining and improving airflow distribution uniformity at a heat exchanger surface according to the above embodiments can be used in a compact size cooling system.

### REFERENCE SIGNS LIST

10 POWER LINE
11 COOLING UNIT BODY
12 HEAT EXCHANGER
13 GAS HEADER
14 LIQUID HEADER
15 AIRFLOW OUTLET
16 FAN
161 SIGNAL LINE
17 FAN
171 SIGNAL LINE
18 AIRFLOW INLET
21 COOLING UNIT BODY
22 HEAT EXCHANGER
23 GAS HEADER
24 LIQUID HEADER
25 AIRFLOW OUTLET
26 FAN
261 SIGNAL LINE
265 AIR VELOCITY SENSOR
27 FAN
271 SIGNAL LINE
275 AIR VELOCITY SENSOR
28 AIRFLOW INLET
200 CONTROL UNIT
31 COOLING UNIT BODY
32 HEAT EXCHANGER
33 GAS HEADER
34 LIQUID HEADER
35 AIRFLOW OUTLET
36 FAN
37 FAN
38 AIRFLOW INLET
40a POWER LINE
40b POWER LINE
41 COOLING UNIT BODY
42 HEAT EXCHANGER
43 GAS HEADER
44 LIQUID HEADER
45 AIRFLOW OUTLET
46 FAN
461 SIGNAL LINE
47 FAN
471 SIGNAL LINE
48 AIRFLOW INLET
400 CONTROL UNIT
50a POWER LINE
50b POWER LINE
501 FAN CASING
51 COOLING UNIT BODY
52 HEAT EXCHANGER
53 GAS HEADER
54 LIQUID HEADER
55 AIRFLOW OUTLET
56 FAN
57 FAN
561 SIGNAL LINE
571 SIGNAL LINE
58 AIRFLOW INLET
61 COOLING UNIT BODY
62 HEAT EXCHANGER
63 GAS HEADER
64 LIQUID HEADER
66 FAN
67 FAN
68 AIRFLOW INLET
69 AIRFLOW INTERRUPTION PLATE
691 AIRFLOW INTERRUPTION CASING
71 COOLING UNIT BODY
72 HEAT EXCHANGER
73 GAS HEADER
74 LIQUID HEADER
76 FAN
77 FAN
78 AIRFLOW INLET
79 AIR FILTER
791 AIR FILTER CASING

1. A system comprising:
a cooling unit body having an airflow inlet and an airflow outlet;
a heat exchanger provided inside the cooling unit body; and
a plurality of fans provided at the airflow inlet.

2. A system according to claim 1, further comprising a plurality of air velocity sensors provided at the heat exchanger, the plurality of air velocity sensors provided corresponding to the plurality of fans.

3. A system according to claim 1, wherein the cooling unit body is installed between a rack top surface and a ceiling.

4. A system according to claim 1, wherein the plurality of fans are configured to be connected to respective power lines and to be connected to respective signal lines.

5. A system according to claim 1, further comprising a controller connected via separate signal lines to the plurality of fans, the controller configured to control the plurality of fans.

6. A system according to claim 5, wherein the controller is configured to set a fan operation set point and fetch a current fan operation point.

7. A system according to claim 6, wherein the controller is further configured to calculate an absolute difference value between the set operation points and an actual operation points;
compare the absolute difference value with a threshold value; and
if any fan has the absolute difference value greater than threshold value,
set a redundant fan operation set point to the plurality of fans.

8. A system according to claim 1, wherein the plurality of fans are shifted towards one header of the heat exchanger so that the distance between the fan and the heat exchanger increases.

9. A system according to claim 1, further comprising a casing in which the plurality of fans are placed, wherein the casing is detachable and can be removed without having to uninstall the cooling unit body from an installed location.

10. A system according to claim 1, further comprising an air interruption casing provided below the fan and configured to receive an air interruption plate.

11. A system according to claim 1, further comprising an air filter casing which is removable without having to uninstall the fan casing.

12. A method of tuning a fan operation in a system including: a cooling unit body having an airflow inlet and an airflow outlet; a heat exchanger provided inside the cooling unit body; and a plurality of fans provided at the airflow inlet, wherein the plurality of fans are configured to be connected to respective power lines and to be connected to respective signal lines, the method comprising:
setting a fan operation point to the plurality of fans;
fetching actual fan operation points for the plurality of fans;
calculating an absolute difference value between the set operation points and the actual operation points;
comparing the absolute difference value with a threshold value; and
if any fan has an absolute difference value greater than the threshold value,
setting a redundant fan operation set point to the plurality of fans.

13. The method according to claim 12, comprising:
if any fan has an absolute difference value greater than the threshold value,
then flagging the fan for maintenance.

14. The method according to claim 12, wherein the redundant fan operation set point is higher than a normal fan operation set point.

15. The method according to claim 12, comprising:
selecting a fan to be tuned;
selecting one or more air velocity sensors corresponding to the selected fan from a plurality of air velocity sensors provided at the heat exchanger;
fetching an air velocity value from one of the selected one or more air velocity sensors;
fetching an air velocity value from one of the full set of air velocity sensors;
comparing the air velocity value from the selected set of air velocity sensor with that of the full set of air velocity sensors;
increasing a fan operation point by single step if the air velocity value from selected set of air velocity sensor is smaller than that of one of the full set of air velocity sensors; and
decreasing a fan operation point by single step if the air velocity value from one of the selected set of air velocity sensors is greater than that of one of the full set of air velocity sensors.

16. The method according to claim 15, wherein the air velocity of the selected sensor is compared with the remaining set of air velocity sensors.

17. A non-transitory computer readable storage medium storing instructions to cause a computer to perform the steps of:
setting a fan operation point;
fetching a current fan operation point;
calculating a difference between the set fan operation point and the current fan operation point; and
comparing the difference between the set fan operation point and the current fan operation point with a threshold value.
